(19) United States
(12) Patent Application Publication
(10) Pub. No.: US 2009/0256642 A1
(43) Pub. Date: Oct. 15, 2009

(54) LOCKED-LOOP CIRCUIT

(76) Inventor: John Paul Lesso, Edinburgh (GB)

Correspondence Address: DICKSTEIN SHAPIRO LLP, 1825 EYE STREET NW, Washington, DC, 20006-5403, US

(21) Appl. No.: 12/419,834

(22) Filed: Apr. 7, 2009

(30) Foreign Application Priority Data
Apr. 9, 2008 (GB) 0806447.9

(51) Int. Cl. H03L 7/085

(52) U.S. Cl. 331/1 A

(57) ABSTRACT

A locked loop circuit, comprising: an input, for receiving an input signal; controllable modification circuitry for generating a signal; an output for the generated signal; a feedback loop for the generated signal; a comparator for comparing the input signal and a signal from the feedback loop, and for producing a comparison signal; circuitry for controlling the modification circuitry on the basis of the comparison signal; and dither circuitry, for adjusting the comparison signal by applying a dither value, where the dither value is non-zero at all times.

### BACKGROUND OF THE INVENTION

1. Field of the Invention

This invention relates to locked-loop circuits, e.g. phase, frequency and delay locked-loop circuits, and in particular to a method for applying dither to such circuits.

2. Description of the Related Art

Power converters are well-known sources of electromagnetic interference. Switching converters and DC-DC converters, when clocked at frequencies in the order of megahertz, will generate substantial tones at the fundamental frequency and its harmonics.

These tones may cause problems for other components in, and possibly around, the associated system. Electromagnetic (EM) pulses radiated from an integrated circuit for example may cause malfunction in other parts of the system and possibly beyond. Further, in audio applications, the tones may react with non-linearities in the system and mix down in frequency, creating tones that are audible to the user.

FIG. 1 shows a standard power converter system 10. An incoming voltage Vᵢₙ is input to a power converter 20 and converted to an output voltage Vₒᵤₜ, with the converter 20 being clocked at a frequency f_{c}. Vₒᵤₜ may be greater than Vᵢₙ (as in boost converters) or less than Vᵢₙ (as in buck converters). A locked-loop circuit 30 receives a reference signal with, or representing a, frequency f_{REF} and generates a clock signal with frequency f_{c}.

There are many other uses of such locked-loop circuits. Locked-loop circuits are well known in the art, and come in many different forms. The most well known locked loop is arguably the phase locked-loop (PLL) circuit, whereby the phase difference between an input signal and an output signal is locked. Other locked loop circuits include the frequency locked loop (FLL), whereby the frequency difference between an input signal and an output signal is locked, and the delay-locked loop (DLL), whereby the delay between an input signal and an output signal is locked.

FIG. 2 is a schematic graph highlighting harmonic tone generation. Sharp tones are created at the odd harmonic frequencies for a clock signal operating at a clock frequency f_{c}. The generation of tones at the odd harmonics arises from the Fourier transform of a square wave clock signal. As aforementioned, these tones are undesirable.

### SUMMARY OF THE INVENTION

According to a first aspect of the invention, there is provided a locked loop circuit, comprising: an input, for receiving an input signal; controllable modification circuitry, for generating a signal; an output for the generated signal; a feedback loop, for the generated signal; a comparator, for comparing the input signal and the signal from the feedback loop, and for producing a comparison signal; means for controlling the modification circuitry on the basis of the comparison signal; and dither circuitry, for adjusting the comparison signal by applying a dither value, wherein the dither value is non-zero at all times.

According to a second aspect of the invention, there is provided a method of applying dither in a locked-loop circuit, comprising: receiving an input signal; generating a signal with controllable modification circuitry; outputting the generated signal; feeding back the generated signal in a feedback loop; comparing the input signal and the signal from the feedback loop, and producing a comparison signal; controlling the modification circuitry on the basis of the comparison signal; and adjusting the comparison signal by applying a dither value, wherein the dither value is non-zero at all times.

### BRIEF DESCRIPTION OF THE DRAWINGS

For a better understanding of the present invention, and to show more clearly how it may be carried into effect, reference will now be made, by way of example, to the following drawings, in which:

FIG. 1 shows a standard power converter system;

FIG. 2 is a schematic graph showing tones present in a conventional power converter system;

FIG. 3 is a schematic diagram showing a frequency locked-loop circuit according to the present invention;

FIG. 4 is a schematic diagram showing a delay locked-loop circuit according to the present invention; and

FIG. 5 is a schematic graph showing tones once dither has been applied according to the present invention.

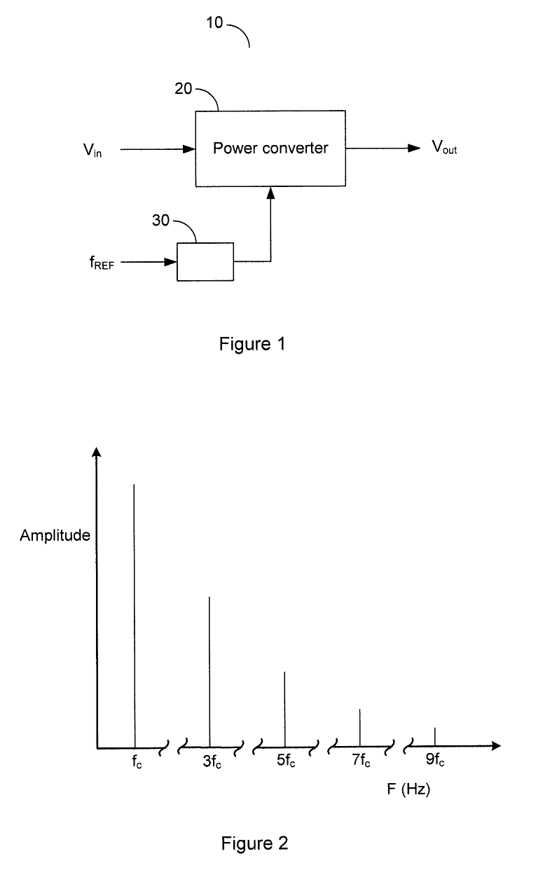

### DETAILED DESCRIPTION OF THE INVENTION

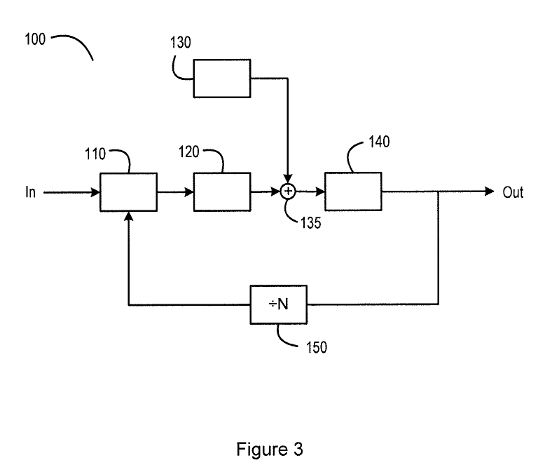

FIG. 3 shows a frequency locked-loop (FLL) circuit 100 according to the present invention. The FLL circuit 100 is generally conventional except for the addition of a dither signal according to the present invention. Thus it will be understood by those skilled in the art that the FLL circuit 100 illustrated is just one example of a possible FLL circuit; alternative FLL circuits may comprise different features and yet still fall within the scope of the invention as defined by the claims.

The FLL circuit 100 generally receives an input signal having a frequency Fᵢₙ, and outputs an output signal having a frequency Fₒᵤₜ. The FLL circuit 100 comprises a frequency detector 110 that detects the frequency of the input signal and compares it with the frequency of a fed back signal. The frequency detector 110 outputs a comparison signal indicative of the compared frequencies; for example, the comparison signal may represent the frequency difference, or a ratio of the two frequencies. The comparison signal is received in a low-pass filter 120, which outputs a filtered signal.

In a conventional FLL circuit, the filtered signal is used to control a voltage-controlled oscillator (VCO); a higher value of the filtered signal results in a higher frequency output from the VCO, and vice versa. The output signal from the VCO is then fed back and input to the frequency detector. In the feedback loop, a ÷N block divides the frequency of the fed back signal by a factor N. This forces the output of the FLL circuit to lock at a frequency of Fₒᵤₜ=N×Fᵢₙ.

The FLL circuit 100 according to the present invention works in a similar manner to a conventional FLL circuit, but with the addition of a dither signal. That is, the FLL circuit 100 comprises a dither block 130 that generates a dither signal, and passes it to an adder 135, where it is combined with the filtered signal output from the low-pass filter 120. The combined signal is used to control a VCO 140, which accordingly outputs a signal with a frequency Fₒᵤₜ. The output signal is fed back to the frequency detector 110, with the feedback loop optionally containing a ÷N block 150 that divides the frequency of the fed back signal by a factor N.

Dither is a noise signal that is intentionally added to a signal. In some applications, dither is used to increase the accuracy of a truncated signal. In the present application, the dither is used to slightly spread the output frequency Fₒᵤₜ so that not all of the energy radiated by the power converter is concentrated at one output frequency and its harmonics. That is, the distribution of power is spread over a range of frequencies and hence the peaks of the fundamental and its harmonics are reduced.

Conventional dither systems comprise a random (or pseudorandom) number generator that, for example, generates a random sequence of 1s and 0s. These random numbers are then added directly to the system as a dither signal. However, these systems have the disadvantage that an average value of ½ is added to the signal. This skew in the output frequency must be compensated in other parts of the system, or otherwise tolerated.

An alternative approach that does not affect the output frequency of the system is to use a 2-bit random number generator, generating values of −1, 0 and +1. Thus the average input to the system caused by the dither is zero. However, these systems do not reduce tones sufficiently.

According to the present invention, the dither block 130 generates a dither signal that takes a range of values with a mean value of zero, but never instantaneously being equal to zero. For example, the dither block 130 may comprise a random (or pseudorandom) number generator that generates a sequence of “−1”s and “+1”s. Examples of possible random number generators include a linear feedback shift register, or a loop circuit with an unstable feedback loop. However, any sequence of numbers is contemplated that does not include the value of zero, yet has a mean value of zero. That is, the sequence may comprise values selected from −3 and +3, etc. Alternatively, a 2-bit random number generator may generate a sequence from the values of, say, −5, −2, +2 and +5. In practice, a compromise must be reached between tone reduction and lack of stability in the output signal.

As aforementioned, the dither signal may be generated by a random or pseudorandom number generator on its own. Alternatively, the random or pseudorandom number generator may operate in conjunction with a multiplexor that receives the randomly generated number and then selects a dither value on the basis of the randomly generated number.

By always adding a non-zero dither value to the system, the tones in the output signal are greatly reduced. Further, by ensuring that the average dither value is zero, the average output signal is not affected.

In the description above, reference has been made to non-zero dither values. However, it will be apparent to those skilled in the art that a nominal zero dither value may be used provided that an offset is also added to the system. For example, an offset of +1 may be added to the system separately from the dither signal added by the dither block 130. In this case, the dither values added by the dither block may be −2 and 0, giving net dither values of −1 and +1. Further, the offset may be added to the FLL circuit 100 at a different point from the dither value. Moreover, although FIG. 3 shows the dither value being added after the filter 120 and before the VCO 140, either the dither value or any offset value may be added at a different point in the circuit. If either the dither value or the offset were added to the FLL circuit 100 prior to the low-pass filter 120, that input would first have to be adapted by the inverse function of the filter 120. That is, the low-pass filter 120 will have some effect on the comparison signal. Therefore if the dither value or the offset is applied prior to the filter 120, the inverse of that effect must be applied so that the filter 120 does not filter it out.

Therefore, in the description above and below and in the claims appended hereto, references to “non-zero” dither values are to be considered to include such embodiments.

The above description has focussed on a frequency locked-loop circuit. However, as mentioned above, many locked-loop circuits are known, and the present invention is in principle applicable to other locked-loop circuits.

For example, the description above is equally applicable to a phase locked-loop (PLL) circuit. The only major changes to the features of the FLL circuit 100 are that the frequency detector 110 would be a phase detector, and the output of the phase detector would be indicative of the phase difference between the input signal and the fed back signal.

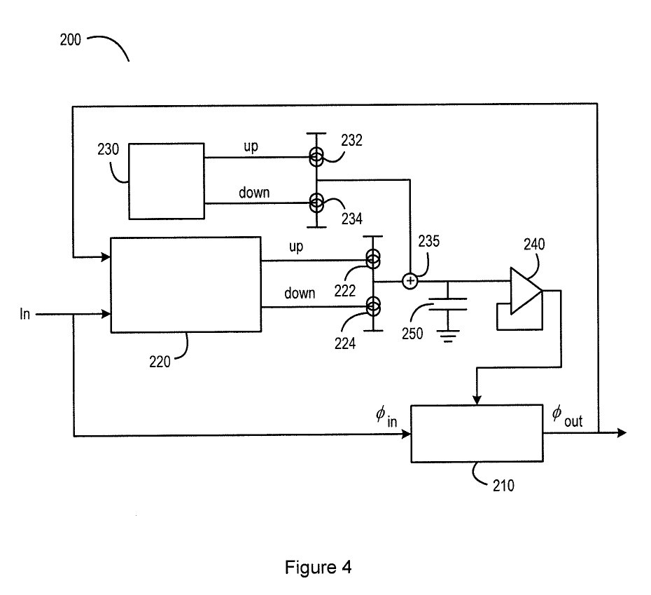

FIG. 4 shows a delay locked-loop (DLL) circuit 200 according to the present invention.

The DLL circuit 200 comprises a voltage-controlled delay line (VCDL) 210. The VCDL 210 receives an input signal having a first phase φᵢₙ, delays the input signal and outputs an output signal having a second phase φₒᵤₜ. The VCDL 210 has a further input that controls the length of the delay.

The input signal is also input to a phase/frequency detector 220, and the output signal is also fed back to the phase/frequency detector 220. The phase/frequency detector 220 compares the two signals and controls two current sources 222, 224 on the basis of the comparison. The current sources 222, 224 act as a potential divider to generate a voltage signal between them. The current sources 222, 224 may be any current sources that will be familiar to those skilled in the art; for example, the current sources 222, 224 may be variable resistors.

In conventional DLL circuits, the comparison signal so generated is used to control the VCDL 210, via a stabilizing capacitor 250 and a buffer 240.

According to the present invention, however, a dither signal is generated by action of a dither block 230. The dither block 230 controls two current sources 232, 234 to operate as a potential divider, similarly to the two current sources 222, 224 coupled to the phase/frequency detector 220. Again, the two current sources 232, 234 may be any current sources familiar to those skilled in art, for example, two resistors. A node connected between the two current sources 232, 234 outputs a voltage which is a dither signal. The dither signal is combined, in an adder 235, with the main comparison signal output from the current sources 222, 224 connected to the phase/frequency detector 220. The combined signal is then fed as a first input to a comparator 240, via a stabilizing capacitor 250. One node of the capacitor 250 is connected to the combined signal, and the other node is connected to ground. The output of the comparator is fed back to a second input to the comparator 240, so that the comparator 240 acts as an integrating buffer. The output of the comparator 240 is then used as the controlling input to the VCDL 210. The action of the DLL circuit 200 as a whole is therefore to maintain a constant delay (usually of multiple clock cycles) between an input signal and an output signal.

According to the present invention, as before, the dither block 230 controls the two current sources 232, 234 so that a non-zero dither value is added to the comparator output.

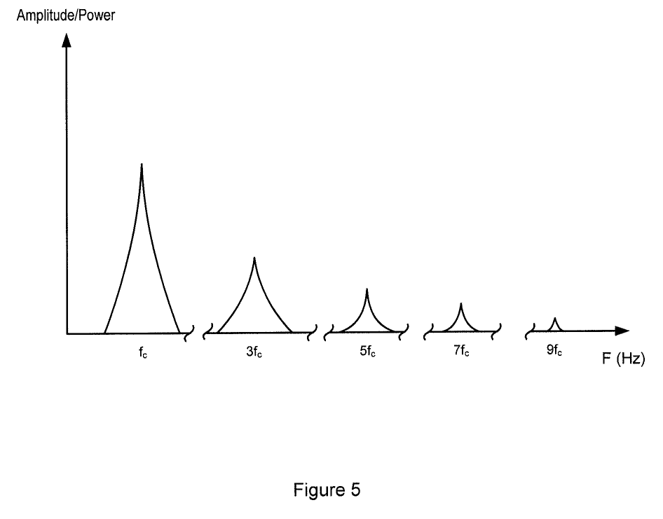

FIG. 5 is a schematic graph showing the profiles of the peaks once dither has been applied. That is, it can be seen that the peaks are spread out over a range of frequencies, and moreover the maximum amplitude of each peak is reduced.

The present invention has therefore provided a method of applying dither to a locked-loop circuit, which greatly reduces the problem of tonal behaviour in such circuits.

The locked-loop circuits described herein preferably form part of a power converter that is preferably incorporated in an integrated circuit. For example, the integrated circuit may be part of an audio and/or video system, such as an MP3 player, a mobile phone, a camera or a satellite navigation system, and the system can be portable (such as a battery-powered handheld system) or can be mains-powered (such as a hi-fi system or a television receiver) or can be an in-car, in-train, or in-plane entertainment system.

The skilled person will recognise that the above-described apparatus and methods may be embodied as processor control code, for example on a carrier medium such as a disk, CD- or DVD-ROM, programmed memory such as read only memory (firmware), or on a data carrier such as an optical or electrical signal carrier. For many applications, embodiments of the invention will be implemented on a DSP (digital signal processor), ASIC (application specific integrated circuit) or FPGA (field programmable gate array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (very high speed integrated circuit hardware description language). As the skilled person will appreciate, the code may be distributed between a plurality of coupled components in communication with one another. Where appropriate, the embodiments may also be implemented using code running on a field-(re-)programmable analogue array or similar device in order to configure analogue/digital hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

What is claimed is:

1. A locked loop circuit, comprising:
an input, for receiving an input signal;
controllable modification circuitry, for generating a signal;
an output for the generated signal;
a feedback loop, for the generated signal;
a comparator, for comparing the input signal and a signal from the feedback loop, and for producing a comparison signal;
means for controlling the modification circuitry on the basis of the comparison signal; and
dither circuitry, for adjusting the comparison signal by applying a dither value, wherein the dither value is non-zero at all times.

2. A locked-loop circuit as claimed in claim 1, wherein said comparator comprises a phase detector, and wherein said comparison signal is indicative of the phase difference between the input signal and the signal from the feedback loop.

3. A locked-loop circuit as claimed in claim 1, wherein said controllable modification circuitry comprises a voltage-controlled oscillator.

4. A locked-loop circuit as claimed in claim 1, wherein said controllable modification circuitry comprises a voltage-controlled delay line.

5. A locked-loop circuit as claimed in claim 1, wherein said comparator comprises a frequency detector, and wherein said comparison signal is indicative of the frequency difference between the input signal and the signal from the feedback loop.

6. A locked-loop circuit as claimed in claim 5, wherein said feedback loop comprises a ÷N block.

7. A locked-loop circuit as claimed in claim 5, wherein said controllable modification circuitry comprises a voltage-controlled oscillator.

8. A locked-loop circuit as claimed in claim 1, wherein said dither circuitry comprises a random-number generator for generating a random signal, and a multiplexer for selecting said dither value on the basis of said random signal.

9. A locked-loop circuit as claimed in claim 8, wherein said random-number generator comprises a loop circuit with an unstable feedback loop.

10. A locked-loop circuit as claimed in claim 8, wherein said random-number generator comprises a linear feedback shift register.

11. A locked-loop circuit as claimed in claim 1, wherein said dither value comprises an intermediate dither value and an offset, and wherein said intermediate dither value may take a value of zero.

12. A locked-loop circuit as claimed in claim 11, wherein said offset is applied at a different point in the circuit to said intermediate dither value.

13. An integrated circuit, comprising a locked-loop circuit as claimed in claim 1.

14. An audio system, comprising an integrated circuit as claimed in claim 13.

15. An audio system as claimed in claim 14, wherein the audio system is a portable device.

16. An audio system as claimed in claim 14, wherein the audio system is a mains-powered device.

17. An audio system as claimed in claim 14, wherein the audio system is an in-car, in-train, or in-plane entertainment system.

18. A video system, comprising an integrated circuit as claimed in claim 13.

19. A video system as claimed in claim 18, wherein the video system is a portable device.

20. A video system as claimed in claim 18, wherein the video system is a mains-powered device.

21. A video system as claimed in claim 18, wherein the video system is an in-car, in-train, or in-plane entertainment system.

22. A method of applying dither in a locked-loop circuit, comprising:
receiving an input signal;
generating a signal with controllable modification circuitry;
outputting the generated signal;
feeding back the generated signal in a feedback loop;
comparing the input signal and a signal from the feedback loop, and producing a comparison signal;
controlling the modification circuitry on the basis of the comparison signal; and
adjusting the comparison signal by applying a dither value, wherein the dither value is non-zero at all times.

23. A method as claimed in claim 22, wherein said step of comparing comprises:
comparing the phase of the input signal and the signal from the feedback loop, wherein said comparison signal is indicative of the phase difference between the input signal and the signal from the feedback loop.

24. A method as claimed in claim 22, wherein said step of comparing comprises:
comparing the frequency of the input signal and the signal from the feedback loop, wherein said comparison signal is indicative of the frequency difference between the input signal and the signal from the feedback loop.

25. A method as claimed in claim 24, wherein said feeding back step comprises dividing a frequency represented by said generated signal by a factor N.

26. A method as claimed in claim 22, further comprising:
generating a random signal; and
selecting said dither value on the basis of said random signal.

27. A method as claimed in claim 22, wherein said dither value comprises an intermediate dither value and an offset, and wherein said intermediate dither value may take a value of zero.

28. A method as claimed in claim 27, comprising:
applying said offset at a different point in the circuit to said intermediate dither value.
